(19) United States
(12) Patent Application Publication
(10) Pub. No.: US 2025/0079365 A1
(43) Pub. Date: Mar. 6, 2025

(54) SEMICONDUCTOR PACKAGE FOR INCREASING BONDING RELIABILITY

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(21) Appl. No.: 18/667,796

(22) Filed: May 17, 2024

(30) Foreign Application Priority Data
Aug. 28, 2023 (KR) 10-2023-0113192

(51) Int. Cl. H01L 23/00

(52) U.S. Cl. CPC H01L 24/08; H01L 24/05; H01L 24/06; H01L 24/80; H01L 2224/05541; H01L 2224/06515; H01L 2224/08145; H01L 2224/80379

(57) ABSTRACT

A semiconductor package includes a first semiconductor chip and a second semiconductor chip hybrid-bonded to the first semiconductor chip. The first semiconductor chip includes first main pads, which are apart from each other, and a first bonding insulation layer extending around the first main pads. Each of the first main pads includes first sub main pads apart from each other. The second semiconductor chip includes second main pads, which are spaced apart from each other, and a second bonding insulation layer extending around the second main pads. The second main pads are aligned with the first main pads. Each of the second main pads includes second sub main pads spaced apart from each other. Each of the second sub main pads is bonded to a respective one of the first sub main pads. The second bonding insulation layer is bonded to the first bonding insulation layer.

### CROSS-REFERENCE TO RELATED APPLICATION

This application is based on and claims priority under 35 U.S.C. § 119 to Korean Patent Application No. 10-2023-0113192, filed on Aug. 28, 2023, in the Korean Intellectual Property Office, the disclosure of which is incorporated by reference herein in its entirety.

### BACKGROUND

The inventive concept relates to a semiconductor package, and more particularly, to a semiconductor package enabling the improvement of bonding reliability.

With the trend toward multifunctional, high-capacity, and compact electronic products, semiconductor packages formed by bonding at least two semiconductor chips have been suggested. In such semiconductor packages, bonding reliability between semiconductor chips is very important. When the bonding reliability of semiconductor packages is low, the semiconductor packages may not function properly.

### SUMMARY

The inventive concept provides a semiconductor package capable of increasing bonding reliability.

According to an aspect of the inventive concept, there is provided a semiconductor package including a first semiconductor chip and a second semiconductor chip hybrid-bonded to the first semiconductor chip, wherein the first semiconductor chip includes a plurality of first main pads and a first bonding insulation layer extending around the plurality of first main pads, wherein the plurality of first main pads are spaced apart from each other, and wherein each of the plurality of first main pads includes a plurality of first sub main pads spaced apart from each other, wherein the second semiconductor chip includes a plurality of second main pads and a second bonding insulation layer extending around the plurality of second main pads, wherein the plurality of second main pads are spaced apart from each other, wherein the plurality of second main pads are aligned with the plurality of first main pads, wherein each of the plurality of second main pads includes a plurality of second sub main pads spaced apart from each other, wherein each of the plurality of second sub main pads is bonded to a respective one of the plurality of first sub main pads, and wherein the second bonding insulation layer is bonded to the first bonding insulation layer.

According to another aspect of the inventive concept, there is provided a semiconductor package including a first semiconductor chip and a second semiconductor chip hybrid-bonded to the first semiconductor chip, wherein the first semiconductor chip includes a plurality of first main pads, a first bonding insulation layer extending around the plurality of first main pads, and a support pad, wherein the plurality of first main pads are spaced apart from each other, wherein each of the plurality of first main pads includes a plurality of first sub main pads spaced apart from each other, wherein the plurality of first sub main pads are on the support pad, wherein the second semiconductor chip includes a plurality of second main pads and a second bonding insulation layer extending around the plurality of second main pads, wherein the plurality of second main pads are spaced apart from each other, wherein each of the plurality of second main pads includes a plurality of second sub main pads spaced apart from each other, wherein the second semiconductor chip further includes a support via, and wherein the plurality of second sub main pads are on the support via, wherein each of the plurality of second sub main pads is bonded to a respective one of the plurality of first sub main pads, and wherein the second bonding insulation layer is bonded to the first bonding insulation layer.

According to a further aspect of the inventive concept, there is provided a semiconductor package including a first semiconductor chip and a second semiconductor chip hybrid-bonded to the first semiconductor chip, wherein the first semiconductor chip includes a first substrate structure, a plurality of first main pads on the first substrate structure, and a first bonding insulation structure extending around the plurality of first main pads, wherein the first substrate structure includes a support pad, and wherein the plurality of first main pads are spaced apart from each other, wherein each of the plurality of first main pads includes a plurality of first sub main pads spaced apart from each other, and wherein the plurality of first sub main pads are supported by the support pad, wherein the second semiconductor chip includes a second substrate structure, a plurality of second main pads spaced apart from each other, and a second bonding insulation structure extending around the plurality of second main pads, wherein the second substrate structure includes a support via, wherein each of the plurality of second main pads includes a plurality of second sub main pads spaced apart from each other, wherein the plurality of second sub main pads are supported by the support via, wherein each of the plurality of second sub main pads is bonded to a respective one of the plurality of first sub main pads, and wherein the second bonding insulation structure is bonded to the first bonding insulation structure.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIG. 2 is an enlarged view of a main portion of the semiconductor package of FIG. 1, according to an embodiment;

FIGS. 3A and 3B are respectively perspective views of a first main pad of a first semiconductor chip and a second main pad of a second semiconductor chip in FIG. 1;

FIGS. 4 and 5 are respectively plan views of the first main pad of the first semiconductor chip and the second main pad of the second semiconductor chip in FIG. 1;

FIG. 6 is a cross-sectional view illustrating a process of bonding the first semiconductor chip and the second semiconductor chip, which form the semiconductor package of FIG. 1;

FIG. 7 is a graph of dishing depth with respect to diameter of a main pad of each of the first semiconductor chip and the second semiconductor chip in FIG. 6;

FIG. 8 is a plan view of the semiconductor package of FIG. 1;

FIG. 9 is a plan view illustrating the arrangement of pads in the semiconductor package of FIG. 1;

FIGS. 10 and 11 are respectively plan views of the arrangements of pads of the first semiconductor chip and the second semiconductor chip in FIGS. 8 and 9;

FIG. 12 is a cross-sectional view taken along line A-A′ in FIG. 9;

FIG. 13 is a cross-sectional view of a semiconductor package according to an embodiment;

FIG. 14 is a cross-sectional view of a semiconductor package according to an embodiment;

FIG. 15 is a cross-sectional view of a semiconductor package according to an embodiment;

FIG. 16 is a schematic block diagram of a memory card using a semiconductor package, according to an embodiment; and

FIG. 17 is a schematic block diagram of an electronic system including a semiconductor package, according to an embodiment.

### DETAILED DESCRIPTION OF THE EMBODIMENTS

Hereinafter, embodiments are described in detail with reference to the accompanying drawings. Embodiments may have only one implementation or may be implemented in combination of one or more embodiments. Accordingly, the inventive concept is not limited to one embodiment. As used herein, the singular forms “a”, “an”, and “the” are intended to include the plural forms as well, unless the context clearly indicates otherwise. The drawings may be exaggerated for clarity.

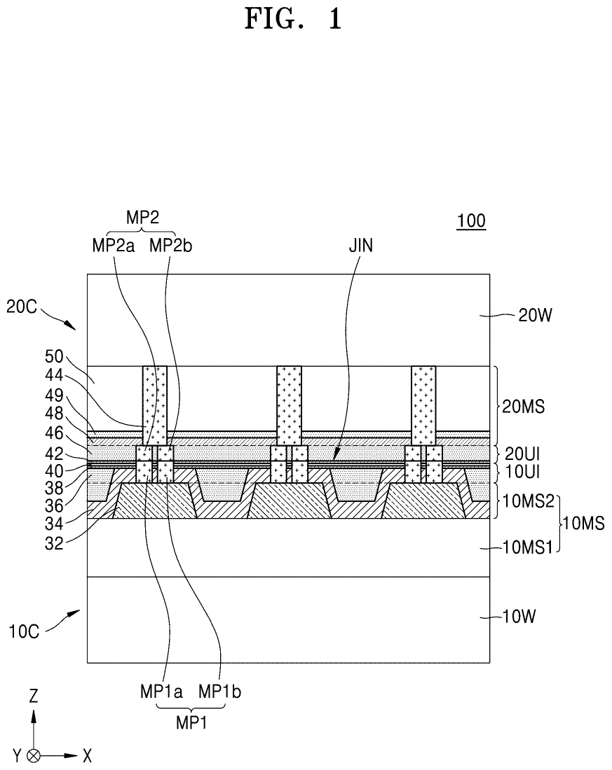

FIG. 1 is a cross-sectional view of a semiconductor package 100 according to an embodiment.

The semiconductor package 100 may include a first semiconductor chip 10C and a second semiconductor chip 20C hybrid-bonded to the first semiconductor chip 10C. The semiconductor package 100 may have a bonding surface JIN at which the second semiconductor chip 20C is hybrid-bonded to the first semiconductor chip 10C.

The semiconductor package 100 includes the second semiconductor chip 20C which is hybrid-bonded on the first semiconductor chip 10C. The semiconductor package 100 includes the first semiconductor chip 10C which is hybrid-bonded on the second semiconductor chip 20C.

Each of the first and second semiconductor chips 10C and 20C may include various kinds of individual devices.

The individual devices may include various microelectronic devices, e.g., a metal-oxide-semiconductor field effect transistor (MOSFET) such as complementary metal-oxide-semiconductor (CMOS) transistor, a system large scale integration (LSI), an image sensor such as a CMOS image sensor (CIS), a micro-electro-mechanical system (MEMS), an active element, and a passive element.

In some embodiments, each of the first and second semiconductor chips 10C and 20C may include at least one selected from the group consisting of a dynamic random access memory (DRAM) chip, a static RAM (SRAM) chip, a flash memory chip, an electrically erasable and programmable ROM (EEPROM) chip, a phase-change RAM (PRAM) chip, a magnetic RAM (MRAM) chip, and a resistive RAM (RRAM) chip.

The first semiconductor chip 10C may include a first substrate 10W, a first substrate structure 10MS, first main pads MP1, and a first bonding insulation structure 10UI. The first substrate 10W may include a silicon substrate. In an embodiment, the first substrate 10W may be removed by a grinding process.

The first substrate structure 10MS may include a first sub substrate structure 10MS1 and a second sub substrate structure 10MS2. The first sub substrate structure 10MS1 may include a through via or an active device, such as a transistor. The second sub substrate structure 10MS2 may include a wiring structure including a wiring layer.

The second sub substrate structure 10MS2 may include a plurality of support pads 32, which are apart from each other. Each of the support pads 32 may include a conductive layer. Each of the support pads 32 may include a metal layer, e.g., an aluminum layer.

The first main pads MP1 may be respectively on the support pads 32. The first main pads MP1 may be apart from each other. Each of the first main pads MP1 may include a conductive layer. The first main pads MP1 may include a different conductive layer than the support pads 32. Each of the first main pads MP1 may include a metal layer, e.g., a copper layer.

Each of the first main pads MP1 may include a plurality of first sub main pads MP1a and MP1b, which are apart from each other. Each of the first main pads MP1 may be divided into the plurality of first sub main pads MP1a and MP1b.

The first bonding insulation structure 10UI may include a first insulating layer 34, a second insulating layer 36, a third insulating layer 38, a fourth insulating layer 40, and a fifth insulating layer 42. Each of the first insulating layer 34, the second insulating layer 36, and the fourth insulating layer 40 may include a silicon oxide layer. Each of the third insulating layer 38 and the fifth insulating layer 42 may include a silicon nitride layer. The first insulating layer 34 may be formed on the sidewalls and top surfaces of the support pads 32.

The second insulating layer 36, the third insulating layer 38, the fourth insulating layer 40, and the fifth insulating layer 42 may be sequentially formed on the first insulating layer 34. The support pads 32 may be insulated from each other by the first bonding insulation structure 10UI and the first main pads MP1 may be insulated from each other by the first bonding insulation structure 10UI.

The fifth insulating layer 42 of the first bonding insulation structure 10UI may be referred to as a first bonding insulation layer. The first bonding insulation structure 10UI including the fifth insulating layer 42, i.e., the first bonding insulation layer, may be between the first sub main pads MP1a and MP1b. Each of the first main pads MP1 may be divided by the first bonding insulation structure 10UI including the fifth insulating layer 42, i.e., the first bonding insulation layer, into the first sub main pads MP1a and MP1b.

In an embodiment, the fifth insulating layer 42 may include a silicon oxide layer. In an embodiment, the fifth insulating layer 42 may include a silicon nitride layer. The top surface of each of the first main pads MP1 may be coplanar with the top surface of the fifth insulating layer 42, i.e., the first bonding insulation layer.

The second semiconductor chip 20C may include a second substrate 20W, a second substrate structure 20MS, second main pads MP2, and a second bonding insulation structure 20UI. The second substrate 20W may include a silicon substrate. An embodiment includes the second substrate 20W. In an embodiment, the second substrate 20W may be removed by a grinding process.

The second substrate structure 20MS may include a plurality of support vias 44 in a silicon layer 50. Each of the support vias 44 may include a conductive layer. Each of the support vias 44 may include a through via passing from the top surface of the second substrate structure 20MS to the bottom surface of the second substrate structure 20MS. Each of the support vias 44 may include a metal layer, e.g., a copper layer.

The second substrate structure 20MS may include an active device such as a transistor. The support vias 44 may be insulated from each other by a first via separating insulation layer 49 and a second via separating insulation layer 48. The first via separating insulation layer 49 may include a silicon oxide layer. The second via separating insulation layer 48 may include a silicon nitride layer.

The second main pads MP2 may be below the support vias 44. The second main pads MP2 may be apart from each other. Each of the second main pads MP2 may include a conductive layer. Each of the second main pads MP2 may include a metal layer, e.g., a copper layer.

Each of the second main pads MP2 may include a plurality of second sub main pads MP2a and MP2b, which are apart from each other. Each of the second main pads MP2 may be divided into the plurality of second sub main pads MP2a and MP2b.

The second bonding insulation structure 20UI may include a sixth insulating layer 46. The sixth insulating layer 46 may include a silicon oxide layer. The sixth insulating layer 46 may be below the second via separating insulation layer 48. The second main pads MP2 may be insulated from each other by the second bonding insulation structure 20UI.

The sixth insulating layer 46 of the second bonding insulation structure 20UI may be referred to as a second bonding insulation layer. The second bonding insulation structure 20UI including the sixth insulating layer 46, i.e., the second bonding insulation layer, may be between the second sub main pads MP2a and MP2b.

Each of the second main pads MP2 may be divided by the second bonding insulation structure 20UI including the sixth insulating layer 46, i.e., the second bonding insulation layer, into the second sub main pads MP2a and MP2b.

In an embodiment, the sixth insulating layer 46 may include a silicon oxide layer. In an embodiment, the sixth insulating layer 46 may include a silicon nitride layer. The bottom surface of each of the second main pads MP2 may be coplanar with the bottom surface of the sixth insulating layer 46, i.e., the second bonding insulation layer.

In the semiconductor package 100, the second main pads MP2 may be positioned in correspondence with (i.e., aligned with) the first main pads MP1, respectively, as illustrated in FIG. 1. The second main pads MP2 may be respectively bonded to the first main pads MP1. The second sub main pads MP2a and MP2b may be respectively bonded to the first sub main pads MP1a and MP1b.

The sixth insulating layer 46, i.e., the second bonding insulation layer, of the second bonding insulation structure 20UI may be bonded to the fifth insulating layer 42, i.e., the first bonding insulation layer, of the first bonding insulation structure 10UI.

In the semiconductor package 100 according to an embodiment, the sixth insulating layer 46, i.e., the second bonding insulation layer, and the fifth insulating layer 42, i.e., the first bonding insulation layer, are respectively formed as a silicon oxide layer and a silicon nitride layer. However, the first and second bonding insulation layers may be respectively formed as silicon oxide layers or silicon nitride layers.

When the second sub main pads MP2a and MP2b, into which each of the second main pads MP2 is divided, are respectively bonded to the first sub main pads MP1a and MP1b, into which each of the first main pads MP1 is divided, the bonding stress in the semiconductor package 100 may be reduced and the dishing depth of the second sub main pads MP2a and MP2b and the dishing depth of the first sub main pads MP1a and MP1b may be reduced.

In addition, because the semiconductor package 100 includes the support vias 44 supporting the second main pads MP2 and the support pads 32 supporting the first main pads MP1, the bonding surface JIN may be flat when the second main pads MP2 are bonded to the first main pads MP1.

As a result, the semiconductor package 100 may significantly increase the bonding reliability between the first semiconductor chip 10C and the second semiconductor chip 20C by including the second sub main pads MP2a and MP2b, the first sub main pads MP1a and MP1b, the support vias 44, and the support pads 32.

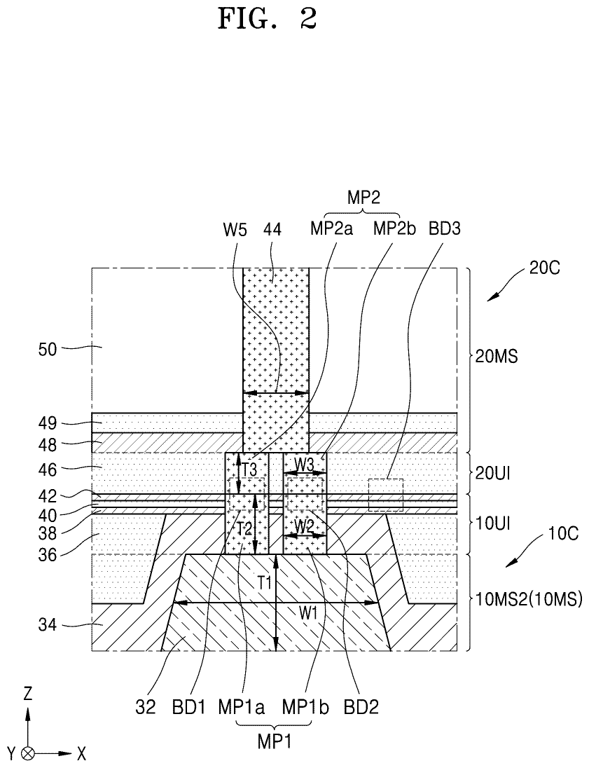

FIG. 2 is an enlarged view of a main portion of the semiconductor package 100 of FIG. 1, according to an embodiment.

Redundant descriptions given above with reference to FIG. 1 are brief or omitted. The semiconductor package 100 may include the second semiconductor chip 20C hybrid-bonded to the first semiconductor chip 10C.

The first semiconductor chip 10C may include the first substrate structure 10MS, the first main pads MP1, and the first bonding insulation structure 10UI. The first substrate structure 10MS may include the second sub substrate structure 10MS2. The second sub substrate structure 10MS2 may include the support pads 32. Each of the support pads 32 may has a width W1 and a thickness T1. The width W1 and the thickness T1 may be several micrometers.

Each of the first main pads MP1 may include the plurality of first sub main pads MP1a and MP1b. Each of the first sub main pads MP1a and MP1b may have a width W2 and a thickness T2. The width W1 of each of the support pads 32 may be greater than a width of each of the first main pads MP1 or a width of the first sub main pads MP1a and MP1b. The width W2 and the thickness T2 may be several micrometers.

The first bonding insulation structure 10UI may include the first insulating layer 34, the second insulating layer 36, the third insulating layer 38, the fourth insulating layer 40, and the fifth insulating layer 42. The fifth insulating layer 42 of the first bonding insulation structure 10UI may be referred to as the first bonding insulation layer.

The second semiconductor chip 20C may include the second substrate structure 20MS, the second main pads MP2, and the second bonding insulation structure 20UI. The second substrate structure 20MS may include the support vias 44 in the silicon layer 50. Each of the support vias 44 may have a width W5. The width W5 may be several micrometers. The first via separating insulation layer 49 and the second via separating insulation layer 48 may be around each of the support vias 44.

The second main pads MP2 may be below the support vias 44. Each of the second main pads MP2 may include the second sub main pads MP2a and MP2b. Each of the second sub main pads MP2a and MP2b may have a width W3 and a thickness T3. The width W3 and the thickness T3 may be several micrometers.

In some embodiments, the thickness T3 of each of the second sub main pads MP2a and MP2b may be less than the thickness T2 of each of the first sub main pads MP1a and MP1b. Although it is illustrated that the thickness T3 of each of the second sub main pads MP2a and MP2b is less than the thickness T2 of each of the first sub main pads MP1a and MP1b, the thickness T3 may be the same as the thickness T2.

In some embodiments, the width W3 of each of the second sub main pads MP2a and MP2b may be the same as the width W2 of each of the first sub main pads MP1a and MP1b. Although it is illustrated that the width W3 of each of the second sub main pads MP2a and MP2b is the same as the width W2 of each of the first sub main pads MP1a and MP1b, the width W3 may be different from the width W2. In some embodiments, the width W5 of each of the support vias 44 may be greater than the width W3 of each of the second sub main pads MP2a and MP2b.

The second bonding insulation structure 20UI may include the sixth insulating layer 46. The second main pads MP2 may be insulated from each other by the second bonding insulation structure 20UI. The sixth insulating layer 46 of the second bonding insulation structure 20UI may be referred to as the second bonding insulation layer.

The semiconductor package 100 may include a pad bonding region BD1, in which the second sub main pad MP2a is bonded to the first sub main pad MP1a, a pad bonding region BD2, in which the second sub main pad MP2b is bonded to the first sub main pad MP1b, and an insulating bonding region BD3, in which the second bonding insulation layer is bonded to the first bonding insulation layer.

Accordingly, because the semiconductor package 100 includes the pad bonding regions BD1 and BD2 and the insulating bonding region BD3, the first semiconductor chip 10C and second semiconductor chip 20C may be easily hybrid-bonded to each other.

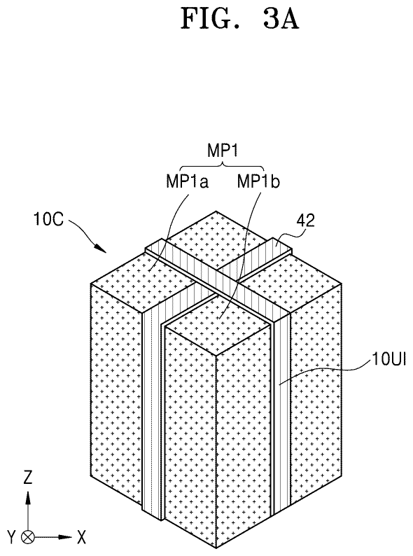

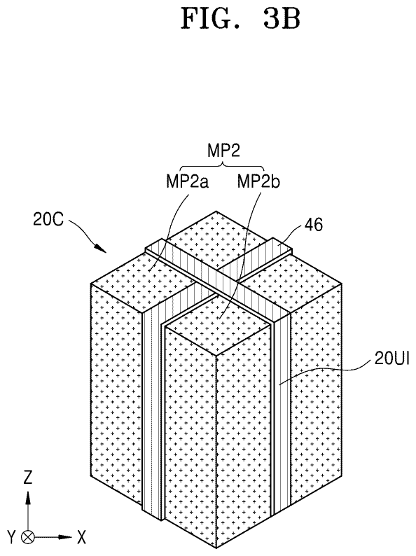

FIGS. 3A and 3B are respectively perspective views of a first main pad MP1 of the first semiconductor chip 10C and a second main pad MP2 of the second semiconductor chip 20C in FIG. 1.

In detail, FIG. 3A is an enlarged view of the first main pad MP1 of the first semiconductor chip 10C in FIG. 1. FIG. 3B is an enlarged view of the second main pad MP2 of the second semiconductor chip 20C in FIG. 1. Redundant descriptions given above with reference to FIG. 1 are brief or omitted.

As shown in FIG. 3A, the first semiconductor chip 10C may include the first main pad MP1. The first main pad MP1 may include a plurality of first sub main pads MP1a and MP1b, which are apart from each other. The first main pad MP1 may be divided into the first sub main pads MP1a and MP1b.

Although it is illustrated in FIG. 3A that the first main pad MP1 is divided into four sub main pads, the first main pad MP1 may be divided into any plural number of sub main pads according to needs. The first main pad MP1 may be divided by the first bonding insulation structure 10UI into the first sub main pads MP1a and MP1b.

The top surface of the first main pad MP1 may be divided by the fifth insulating layer 42, i.e., the first bonding insulation layer, of the first bonding insulation structure 10UI. The first bonding insulation structure 10UI may be formed on the top and side surfaces of the first main pad MP1.

As shown in FIG. 3B, the second semiconductor chip 20C may include the second main pad MP2. The second main pad MP2 may include a plurality of second sub main pads MP2a and MP2b, which are apart from each other. The second main pad MP2 may be divided into the second sub main pads MP2a and MP2b.

Although it is illustrated in FIG. 3B that the second main pad MP2 is divided into four sub main pads, the second main pad MP2 may be divided into any plural number of sub main pads according to needs. The second main pad MP2 may be divided by the second bonding insulation structure 20UI into the second sub main pads MP2a and MP2b.

The top surface of the second bonding insulation structure 20UI may be divided by the sixth insulating layer 46, i.e., the second bonding insulation layer, of the second bonding insulation structure 20UI. The second bonding insulation structure 20UI may be formed on the top and side surfaces of the second main pad MP2.

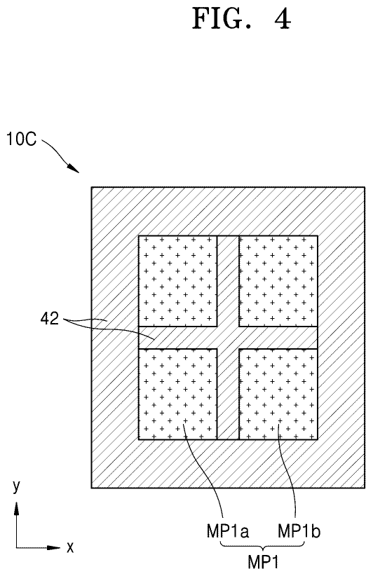

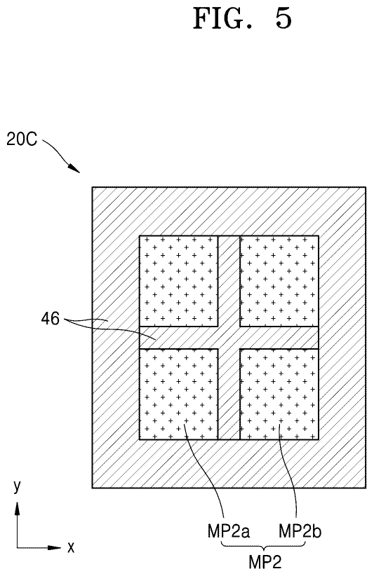

FIGS. 4 and 5 are respectively plan views of the first main pad MP1 of the first semiconductor chip 10C and the second main pad MP2 of the second semiconductor chip 20C in FIG. 1.

In detail, FIG. 4 is an enlarged plan view of the first main pad MP1 of the first semiconductor chip 10C in FIG. 1. FIG. 5 is an enlarged plan view of the second main pad MP2 of the second semiconductor chip 20C in FIG. 1. Redundant descriptions given above with reference to FIG. 1 are brief or omitted.

As shown in FIG. 4, the first semiconductor chip 10C may include the first main pad MP1.

The first main pad MP1 may include a plurality of first sub main pads MP1a and MP1b, which are apart from each other. The first main pad MP1 may be divided into the first sub main pads MP1a and MP1b.

Although it is illustrated in FIG. 4 that the first main pad MP1 is divided into four sub main pads, the first main pad MP1 may be divided into any plural number of sub main pads according to needs. The first main pad MP1 may be divided into the first sub main pads MP1a and MP1b by the fifth insulating layer 42, i.e., the first bonding insulation layer, of the first bonding insulation structure 10UI (in FIG. 1). The fifth insulating layer 42, i.e., the first bonding insulation layer, of the first bonding insulation structure 10UI may surround (e.g., extend around) the first main pad MP1, as illustrated in FIG. 4.

As shown in FIG. 5, the second semiconductor chip 20C may include the second main pad MP2. The second main pad MP2 may include a plurality of second sub main pads MP2a and MP2b, which are apart from each other. The second main pad MP2 may be divided into the second sub main pads MP2a and MP2b.

Although it is illustrated in FIG. 5 that the second main pad MP2 is divided into four sub main pads, the second main pad MP2 may be divided into any plural number of sub main pads according to needs. The second main pad MP2 may be divided into the second sub main pads MP2a and MP2b by the sixth insulating layer 46, i.e., the second bonding insulation layer, of the second bonding insulation structure 20UI (in FIG. 1). The sixth insulating layer 46, i.e., the second bonding insulation layer, of the second bonding insulation structure 20UI may surround (e.g., extend around) the second main pad MP2, as illustrated in FIG. 5.

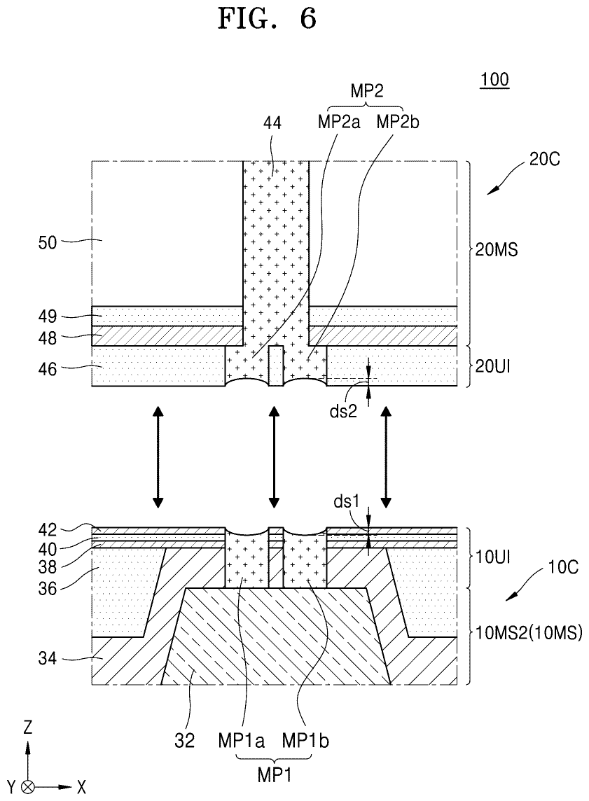

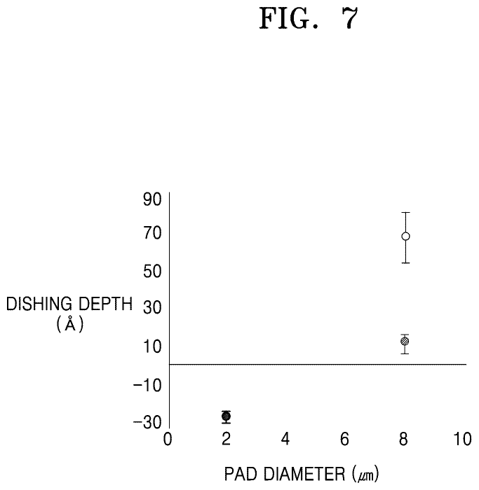

FIG. 6 is a cross-sectional view illustrating a process of bonding the first semiconductor chip 10C and the second semiconductor chip 20C, which form the semiconductor package 100 of FIG. 1. FIG. 7 is a graph of dishing depth with respect to diameter of a main pad of each of the first semiconductor chip 10C and the second semiconductor chip 20C in FIG. 6.

Redundant descriptions given above with reference to FIG. 1 are brief or omitted. In the semiconductor package 100, the second semiconductor chip 20C may be located above and hybrid-bonded to the first semiconductor chip 10C.

The first semiconductor chip 10C may include the first substrate structure 10MS, a first main pad MP1, and the first bonding insulation structure 10UI. The first substrate structure 10MS may include the second sub substrate structure 10MS2. The second sub substrate structure 10MS2 may include a support pad 32. The first main pad MP1 may be formed on the support pad 32. The first main pad MP1 may include a plurality of first sub main pads MP1a and MP1b. The top surface of each of the first sub main pads MP1a and MP1b may be recessed by a dishing depth ds1, as illustrated in FIG. 6.

The first bonding insulation structure 10UI may surround (e.g., extend around) the first main pad MP1. The first bonding insulation structure 10UI may include the first insulating layer 34, the second insulating layer 36, the third insulating layer 38, the fourth insulating layer 40, and the fifth insulating layer 42. The fifth insulating layer 42 of the first bonding insulation structure 10UI may be referred to as a first bonding insulation layer.

The second semiconductor chip 20C may include the second substrate structure 20MS, a second main pad MP2, and the second bonding insulation structure 20UI. The second substrate structure 20MS may include a support via 44 formed in the silicon layer 50. The first via separating insulation layer 49 and the second via separating insulation layer 48 may be formed around the support via 44.

The second main pad MP2 may be arranged below the support via 44. The second main pad MP2 may include a plurality of second sub main pads MP2a and MP2b. The bottom surface of each of the second sub main pads MP2a and MP2b may be recessed by a dishing depth ds2, as illustrated in FIG. 6.

The second bonding insulation structure 20UI may surround (e.g., extend around) the second main pad MP2. The sixth insulating layer 46 of the second bonding insulation structure 20UI may be referred to as a second bonding insulation layer.

The bottom surface of the second main pad MP2 may be bonded to the top surface of the first main pad MP1. The respective bottom surfaces of second sub main pads MP2a and MP2b may be respectively bonded to the respective top surfaces of the first sub main pads MP1a and MP1b. The bottom surface of the sixth insulating layer 46, i.e., the second bonding insulation layer, of the second bonding insulation structure 20UI may be bonded to the top surface of the fifth insulating layer 42, i.e., the first bonding insulation layer, of the first bonding insulation structure 10UI.

The bonding process described above may be performed by performing a high-temperature annealing process on a state in which the second main pad MP2 is attached to the first main pad MP1 and the second bonding insulation layer is attached to the first bonding insulation layer.

In the bonding process for the semiconductor package 100 of FIG. 6, bonding stress may be reduced by respectively bonding the second sub main pads MP2a and MP2b, into which the second main pad MP2 is divided into, to the first sub main pads MP1a and MP1b, into which the first main pad MP1 is divided.

It may be seen in FIG. 7 that the dishing depth decreases when the diameter of each of the first and second main pads MP1 and MP2 of the first semiconductor chip 10C and the second semiconductor chip 20C, respectively, decreases.

Based on the above, when the second main pad MP2 is divided into the second sub main pads MP2a and MP2b and the first main pad MP1 is divided into the first sub main pads MP1a and MP1b, the dishing depths ds1 and ds2 in FIG. 6 may be reduced in the bonding process for the semiconductor package 100 of FIG. 6. Accordingly, the semiconductor package 100 may significantly increase the bonding reliability between the first semiconductor chip 10C and the second semiconductor chip 20C.

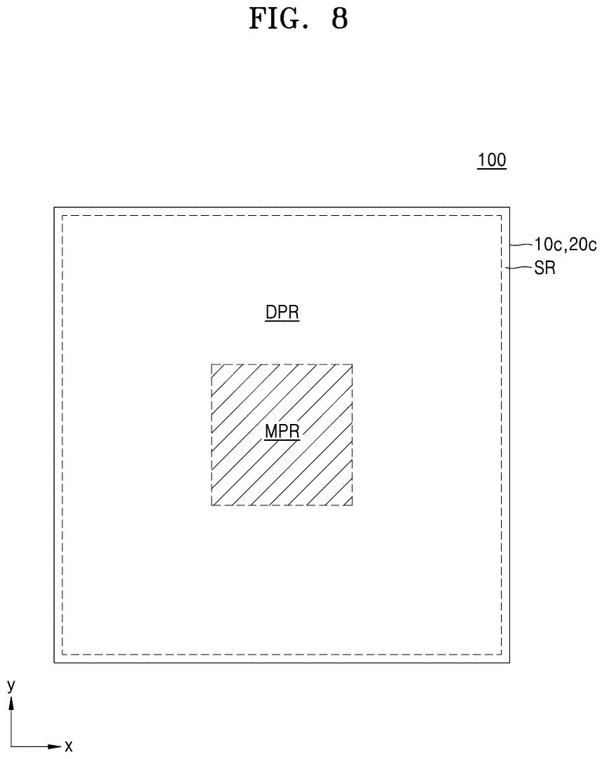

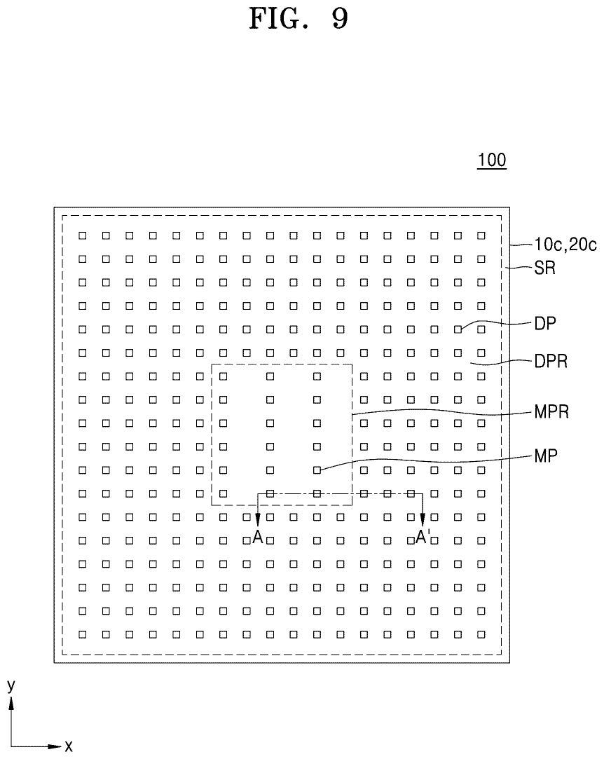

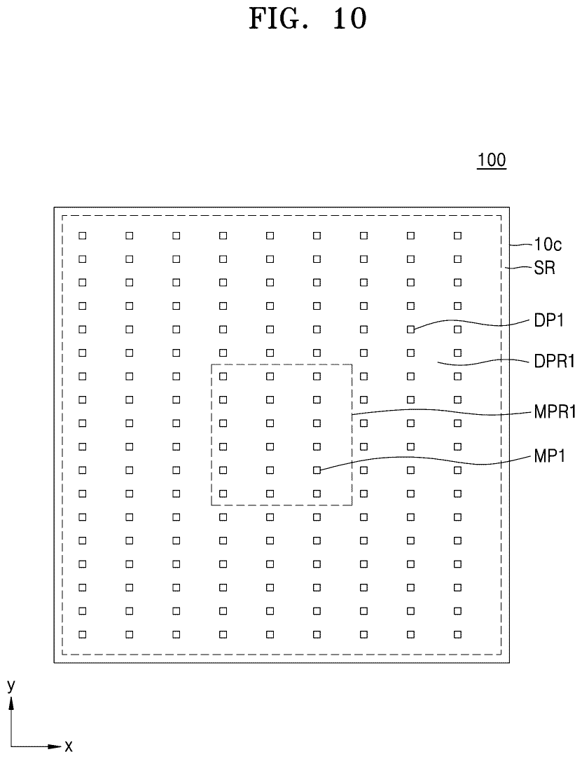

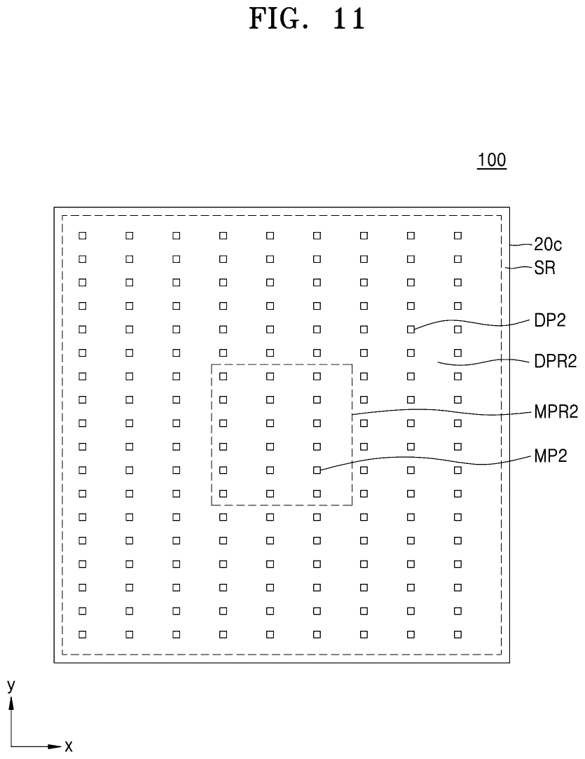

FIG. 8 is a plan view of the semiconductor package 100 of FIG. 1, FIG. 9 is a plan view illustrating the arrangement of pads in the semiconductor package 100 of FIG. 1, and FIGS. 10 and 11 are respectively plan views of the arrangements of pads of the first semiconductor chip 10C and the second semiconductor chip 20C in FIGS. 8 and 9.

Redundant descriptions given above with reference to FIG. 1 are brief or omitted. As shown in FIGS. 8 and 9, the semiconductor package 100 may have a structure in which the first semiconductor chip 10C and the second semiconductor chip 20C are bonded to each other. The semiconductor package 100 may have a structure in which the second semiconductor chip 20C is stacked on and bonded to the first semiconductor chip 10C. The semiconductor package 100 may have a width in the X direction (e.g., a first direction) and a length in the Y direction (e.g., a second direction). The width in the X direction and the length in the Y direction may vary with package structures.

The first semiconductor chip 10C and the second semiconductor chip 20C may have a main pad region MPR in their central regions, a scribe lane region SR in their edge regions, and a dummy pad region DPR between the main pad region MPR and the scribe lane region SR. The dummy pad region DPR may include a peripheral region surrounding (e.g., peripherally surrounding) the main pad region MPR.

Main pads MP may be arranged in the main pad region MPR to be apart from each other. The main pads MP may be referred to as bonding pads. The main pads MP may correspond to a structure that electrically connects the first semiconductor chip 10C to the second semiconductor chip 20C. According to a plan view, the main pads MP may be arranged in the central regions of the first semiconductor chip 10C and the second semiconductor chip 20C.

Dummy pads DP may be arranged in the dummy pad region DPR to be apart from each other. According to a plan view, the dummy pads DP may be arranged in the peripheral regions of the first semiconductor chip 10C and the second semiconductor chip 20C and may surround (e.g., are positioned around) the main pads MP, as illustrated in FIG. 9. The dummy pads DP may correspond to a structure that does not electrically connect the first semiconductor chip 10C to the second semiconductor chip 20C.

As shown in FIG. 10, the first semiconductor chip 10C may include a first main pad region MPR1 forming the main pad region MPR. First main pads MP1 may be arranged in the first main pad region MPR1 to be apart from each other. The first main pads MP1 may be referred to as first bonding pads.

The first semiconductor chip 10C may include a first dummy pad region DPR1 forming the dummy pad region DPR. First dummy pads DP1 may be arranged in the first dummy pad region DPR1 to be apart from each other. The first dummy pads DP1 may be provided to adjust the pad density between the first main pad region MPR1 and the first dummy pad region DPR1.

As shown in FIG. 11, the second semiconductor chip 20C may include a second main pad region MPR2 forming the main pad region MPR. Second main pads MP2 may be arranged in the second main pad region MPR2 to be apart from each other. The second main pads MP2 may be referred to as second bonding pads. The second main pads MP2 may be respectively bonded to the first main pads MP1 of the first semiconductor chip 10C.

The second semiconductor chip 20C may include a second dummy pad region DPR2 forming the dummy pad region DPR. Second dummy pads DP2 may be arranged in the second dummy pad region DPR2 to be apart from each other. The second dummy pads DP2 may be respectively bonded to the first dummy pads DP1 of the first semiconductor chip 10C. The second dummy pads DP2 may be provided to adjust the pad density between the second main pad region MPR2 and the second dummy pad region DPR2.

Although it is illustrated in FIGS. 10 and 11 that each of the first main pads MP1, the second main pads MP2, the first dummy pads DP1, and the second dummy pads DP2 has a square shape according to a plan view, embodiments are not limited thereto. For example, each of the first main pads MP1, the second main pads MP2, the first dummy pads DP1, and the second dummy pads DP2 may have various shapes, such as a rectangular shape, a diamond shape, a rounded square shape, a rounded rectangular shape, an oval shape, and a circular shape.

Although it is illustrated in FIGS. 10 and 11 that neither a first dummy pad DP1 nor a second dummy pad DP2 is arranged in the scribe lane region SR, first dummy pads DP1 and second dummy pads DP2 may be arranged in at least a portion of the scribe lane region SR.

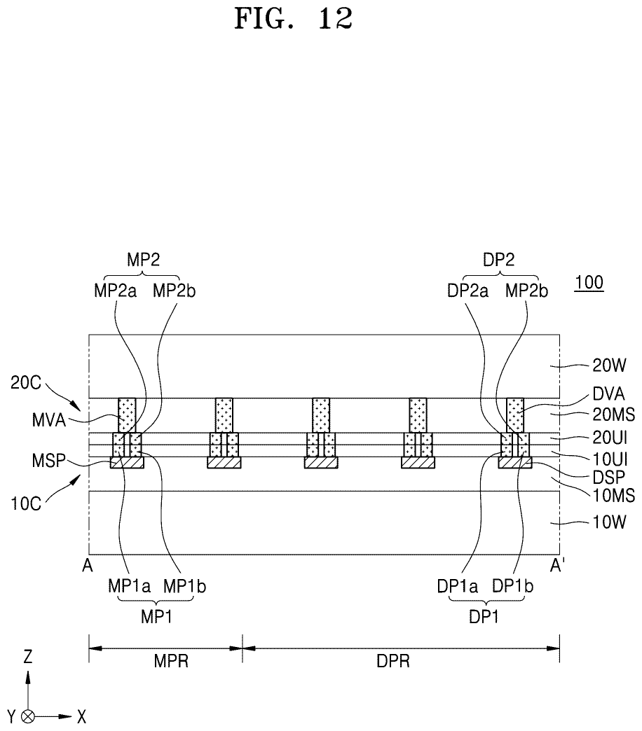

FIG. 12 is a cross-sectional view taken along line A-A′ in FIG. 9.

The semiconductor package 100 may include the second semiconductor chip 20C bonded to the first semiconductor chip 10C. The first semiconductor chip 10C may include first substrate 10W and the first substrate structure 10MS on the first substrate 10W. The second semiconductor chip 20C may include the second substrate 20W and the second substrate structure 20MS below the second substrate 20W.

The first semiconductor chip 10C may include first main pads MP1 and first dummy pads DP1 and the second semiconductor chip 20C may include second main pads MP2 and second dummy pads DP2. Each of the first main pads MP1 may include a plurality of first sub main pads MP1a and MP1b.

A support pad MSP may be below each first main pad MP1 and may support the first main pad MP1. Each of the second main pads MP2 may include a plurality of second sub main pads MP2a and MP2b. A support via MVA may be above each second main pad MP2 and may support the second main pad MP2.

Each of the first dummy pads DP1 may include a plurality of first sub dummy pads DP1a and DP1b. A dummy support pad DSP may be below each first dummy pad DP1 and may support the first dummy pad DP1. Each of the second dummy pads DP2 may include a plurality of second sub dummy pads DP2a and DP2b. A dummy support via DVA may be above each second dummy pad DP2 and may support the second dummy pad DP2.

The first dummy pad DP1 may be apart from the first main pad MP1 and the second dummy pad DP2 may be apart from the second main pad MP2. The first bonding insulation structure 10UI may be on the first substrate structure 10MS of the first semiconductor chip 10C and may surround (e.g., extend around) the first main pads MP1 and the first dummy pads DP1.

The second bonding insulation structure 20UI may be below the second substrate structure 20MS of the second semiconductor chip 20C and may surround (e.g., extend around) the second main pads MP2 and the second dummy pads DP2. The first bonding insulation structure 10UI and the second bonding insulation structure 20UI may include a silicon oxide layer or a silicon nitride layer.

As described above, in the semiconductor package 100, the first main pads MP1 of the first semiconductor chip 10C and the second main pads MP2 of the second semiconductor chip 20C may be respectively bonded to each other. The first dummy pads DP1 of the first semiconductor chip 10C and the second dummy pads DP2 of the second semiconductor chip 20C may be respectively bonded to each other. The first bonding insulation structure 10UI of the first semiconductor chip 10C and the second bonding insulation structure 20UI of the second semiconductor chip 20C may be bonded to each other.

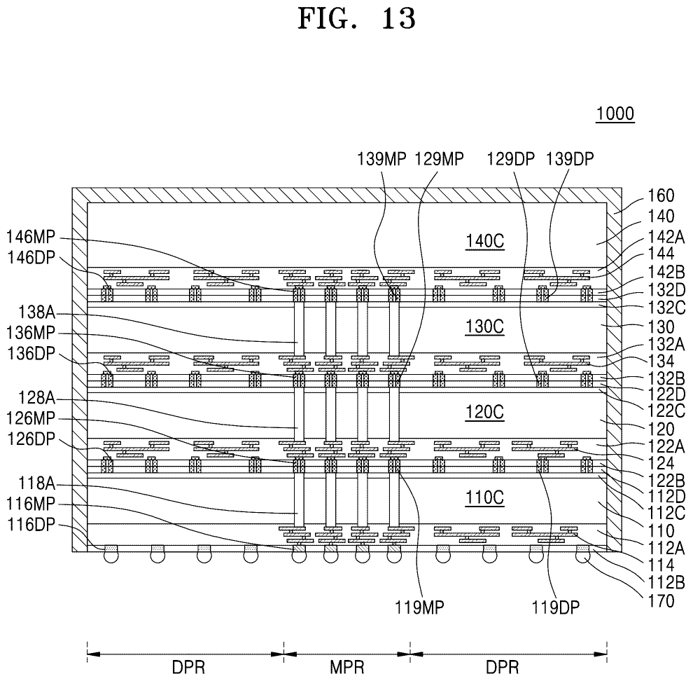

FIG. 13 is a cross-sectional view of a semiconductor package 1000 according to an embodiment.

The semiconductor package 1000 may include a first stacked semiconductor chip 110C, a second stacked semiconductor chip 120C, a third stacked semiconductor chip 130C, and a fourth stacked semiconductor chip 140C. Each of the first stacked semiconductor chip 110C, the second stacked semiconductor chip 120C, the third stacked semiconductor chip 130C, and the fourth stacked semiconductor chip 140C may correspond to the first semiconductor chip 10C or the second semiconductor chip 20C.

The first stacked semiconductor chip 110C may include a wiring layer 114 and an interlayer insulating film 112A, which are on a first surface of a first substrate structure 110. A lower insulating layer 112B, a main pad 116MP, and a dummy pad 116DP may be arranged on the interlayer insulating film 112A.

An upper insulating layer 112C, a bonding insulation layer 112D, a main pad 119MP, and a dummy pad 119DP may be arranged on a second surface of the first substrate structure 110 (or the first substrate). The main pad 119MP may include a plurality of sub main pads, as described above. The dummy pad 119DP may include a plurality of sub dummy pads.

Similarly, the second to fourth stacked semiconductor chips 120C, 130C, and 140C may include wiring layers 124, 134, and 144, respectively, and interlayer insulating films 122A, 132A, and 142A, respectively, on second to fourth substrate structures (or second to fourth substrates) 120, 130, and 140, respectively. Bonding insulation layers 122B, 132B, and 142B, main pads 126MP, 136MP, and 146MP, and dummy pads 126DP, 136DP, and 146DP may be respectively arranged on the interlayer insulating films 122A, 132A, and 142A. A support pad or a dummy support pad may be in a topmost portion of each of the wiring layers 124, 134, and 144.

An upper insulating layer 122C, a bonding insulating layer 112D, a main pad 129MP, and a dummy pad 129DP may be arranged on a second surface of the second substrate structure 120. An upper insulating layer 132C, a bonding insulating layer 132D, a main pad 139MP, and a dummy pad 139DP may be arranged on a second surface of the third substrate structure 130. Each of the main pads 126MP, 136MP, 146MP, 129MP, and 139MP may include a plurality of sub main pads, as described above. Each of the dummy pads 126DP, 136DP, 146DP, 129DP, and 139DP may include a plurality of sub dummy pads.

The first stacked semiconductor chip 110C may include a through via 118A, which passes through the first substrate structure 110, and the main pad 119MP, which is on the second surface of the first substrate structure 110 and connected to the through via 118A. The through via 118A may correspond to the support via described above.

Similarly, the second and third stacked semiconductor chips 120C and 130C may respectively include through vias 128A and 138A, which respectively pass through the second and third substrates 120 and 130, and respectively include the main pads 129MP and 139MP, which are respectively on the second surface of the second substrate structure 120 and the second surface of the third substrate structure 130 and respectively connected to the through vias 128A and 138A. Each of the through vias 128A and 138A may correspond to the support via described above.

The main pad 119MP of the first stacked semiconductor chip 110C may be in contact with the main pad 126MP of the second stacked semiconductor chip 120C. The main pad 129MP of the second stacked semiconductor chip 120C may be in contact with the main pad 136MP of the third stacked semiconductor chip 130C. The main pad 139MP of the third stacked semiconductor chip 130C may be in contact with the main pad 146MP of the fourth stacked semiconductor chip 140C.

The dummy pad 119DP of the first stacked semiconductor chip 110C may be in contact with the dummy pad 126DP of the second stacked semiconductor chip 120C. The dummy pad 129DP of the second stacked semiconductor chip 120C may be in contact with the dummy pad 136DP of the third stacked semiconductor chip 130C. The dummy pad 139DP of the third stacked semiconductor chip 130C may be in contact with the dummy pad 146DP of the fourth stacked semiconductor chip 140C.

A molding material 160 may be further provided to surround (e.g., encapsulate) the top and side surfaces of the first to fourth stacked semiconductor chips 110C, 120C, 130C, and 140C. A connection bump 170 may be attached to each of the main pad 116MP and the dummy pad 116DP on the first surface of the first stacked semiconductor chip 110C. The molding material 160 may include an epoxy mold compound (EMC). In some embodiments, the molding material 160 may cover only the side surfaces of the first to fourth stacked semiconductor chips 110C, 120C, 130C, and 140C or may be omitted.

In embodiments, each of the first to fourth stacked semiconductor chips 110C, 120C, 130C, and 140C may correspond to a memory chip or a logic chip. For example, the first to fourth stacked semiconductor chips 110C, 120C, 130C, and 140C may all be memory chips of the same type or at least one of the first to fourth stacked semiconductor chips 110C, 120C, 130C, and 140C may be a logic chip and the others may be memory chips.

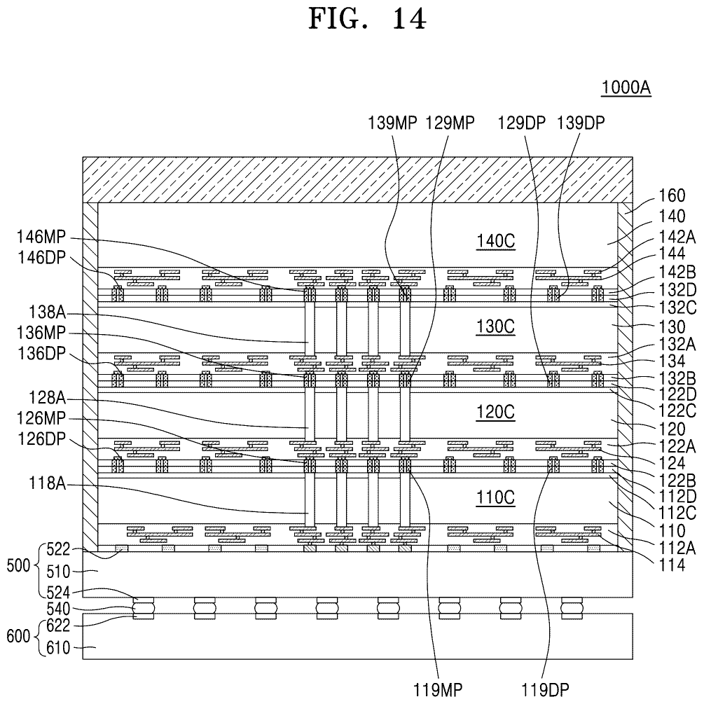

FIG. 14 is a cross-sectional view of a semiconductor package 1000A according to an embodiment.

Compared to the semiconductor package 1000 of FIG. 13, the semiconductor package 1000A may further include an interposer 500. Redundant descriptions given above with reference to FIG. 13 are brief or omitted.

The interposer 500 may include a base layer 510, a first top pad 522, and a first bottom pad 524. In some embodiments, a redistribution layer may be further arranged on the base layer 510. The base layer 510 may include a semiconductor, glass, ceramic, or plastic. For example, the base layer 510 may include silicon.

A through via (not shown) may be further arranged in the base layer 510 to electrically connect the first top pad 522 to the first bottom pad 524. The interposer 500 and the first stacked semiconductor chip 110C may be attached to each other through metal-oxide hybrid bonding using the first top pad 522. Differently, the interposer 500 and the first stacked semiconductor chip 110C may be connected to each other through a connection bump (not shown).

A main board 600 may include a base board layer 610 and a second top pad 622. The first bottom pad 524 of the interposer 500 may be electrically connected to the second top pad 622 of the main board 600 by a board connection terminal 540.

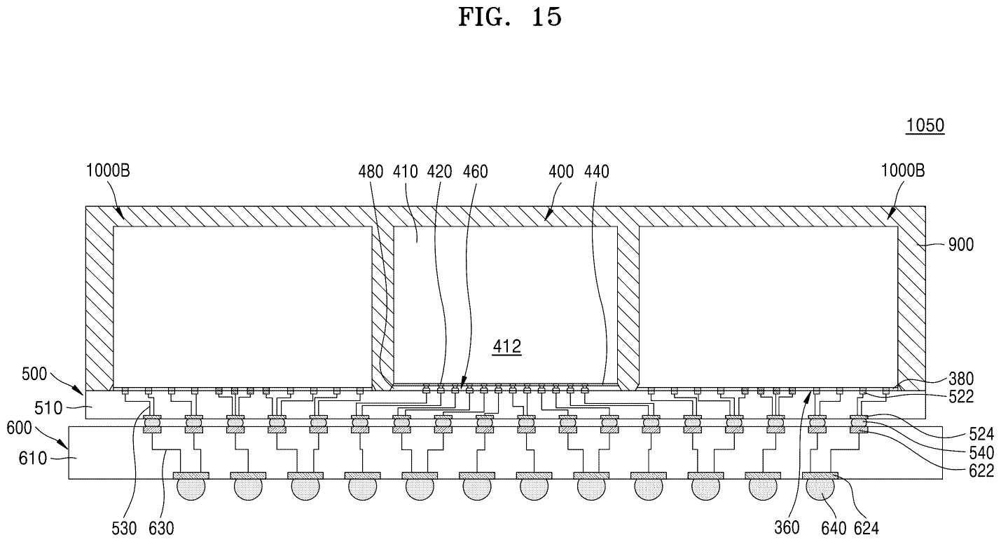

FIG. 15 is a cross-sectional view of a semiconductor package 1050 according to an embodiment.

The semiconductor package 1050 may include the main board 600 on which the interposer 500 is mounted, a sub semiconductor package 1000B including the first to fourth stacked semiconductor chips 110C, 120C, 130C, and 140C (in FIG. 13) attached to the interposer 500, and a fifth semiconductor chip 400. The sub semiconductor package 1000B may correspond to the semiconductor package 1000 described above with reference to FIG. 13. The semiconductor package 1050 may be referred to as a system.

Although it is illustrated in FIG. 15 that the semiconductor package 1050 includes two sub semiconductor packages 1000B, embodiments are not limited thereto. For example, the semiconductor package 1050 may include on sub semiconductor package 1000B or at least three sub semiconductor packages 1000B.

The fifth semiconductor chip 400 may include a fifth substrate structure 410 having a third semiconductor device 412 formed on an active surface thereof, a plurality of top connection pads 420, a front protection layer 440, and a plurality of connection bumps 460 respectively attached to the top connection pads 420. For example, the fifth semiconductor chip 400 may correspond to a central processing unit (CPU) chip, a graphics processing unit (GPU) chip, or an application processor (AP) chip. Each of the top connection pads 420 may include at least one selected from the group consisting of aluminum, copper, and nickel.

The interposer 500 may include the base layer 510, the first top pad 522 on the top of the base layer 510, the first bottom pad 524 on the bottom of the base layer 510, and a first wiring path 530 electrically connecting the first top pad 522 to the first bottom pad 524 through the base layer 510.

The first wiring path 530 may include a wiring layer, which is on the top and/or the bottom of the base layer 510 and connected to the first top pad 522 and/or to the first bottom pad 524, and/or an internal through electrode, which is in the base layer 510 and electrically connects the first top pad 522 to the first bottom pad 524. A connection bump 360, which electrically connects the sub semiconductor package 1000B to the interposer 500, or the connection bump 460, which electrically connects the fifth semiconductor chip 400 to the interposer 500, may be connected to the first top pad 522.

A first underfill layer 380 may be between the sub semiconductor package 1000B and the interposer 500 and a second underfill layer 480 may be between the fifth semiconductor chip 400 and the interposer 500. The first underfill layer 380 may surround (e.g., extend around) the connection bump 360 and the second underfill layer 480 may surround (e.g., extend around) the connection bump 460.

The semiconductor package 1050 may further include a package molding layer 900, which is on the interposer 500 and surrounds (e.g., encapsulates) the side surface of the sub semiconductor package 1000B and the side surface of the fifth semiconductor chip 400. For example, the package molding layer 900 may include an EMC. In some embodiments, the package molding layer 900 may cover the top surface of the sub semiconductor package 1000B and the top surface of the fifth semiconductor chip 400. In some embodiments, the package molding layer 900 may not cover the top surfaces of the sub semiconductor package 1000B and the fifth semiconductor chip 400.

For example, a heat dissipation unit may be attached to each of the sub semiconductor package 1000B and the fifth semiconductor chip 400 with a thermal interface material (TIM) layer between the heat dissipation unit and each of the sub semiconductor package 1000B and the fifth semiconductor chip 400. For example, the TIM layer may include mineral oil, grease, gap filler putty, phase-change gel, a phase-change material pad, or particle-filled epoxy.

For example, the heat dissipation unit may include a heat sink, a heat spreader, a heat pipe, or a liquid-cooled cold plate. The board connection terminal 540 may be attached to the first bottom pad 524. The board connection terminal 540 may electrically connect the interposer 500 to the main board 600.

The main board 600 may include the base board layer 610, the second top pad 622 on the top of the base board layer 610, a second bottom pad 624 on the bottom of the base board layer 610, and a second wiring path 630, which electrically connects the second top pad 622 to the second bottom pad 624 through the base board layer 610.

In some embodiments, the main board 600 may correspond to a printed circuit board (PCB). For example, the main board 600 may correspond to a multi-layer PCB. The base board layer 610 may include at least one material selected from the group consisting of phenol resin, epoxy resin, and polyimide.

A solder resist layer (not shown) may be formed on each of the top and bottom surfaces of the base board layer 610 such that the second top pad 622 and the second bottom pad 624 are exposed. The board connection terminal 540 may be connected to the second top pad 622 and an external connection terminal 640 may be connected to the second bottom pad 624. The board connection terminal 540 may electrically connect the first bottom pad 524 to the second top pad 622. The external connection terminal 640 connected to the second bottom pad 624 may connect the semiconductor package 1050 to the outside (e.g., to an external device/component). In some embodiments, the semiconductor package 1050 may not include the main board 600 and the board connection terminal 540 of the interposer 500 may function as an external connection terminal.

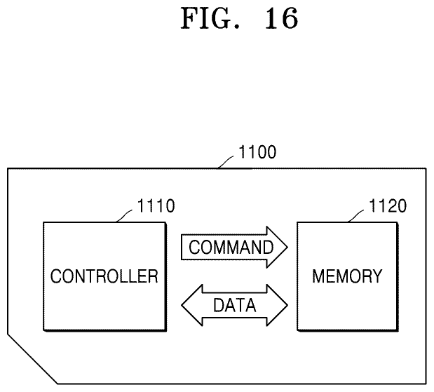

FIG. 16 is a schematic block diagram of a memory card 1100 using a semiconductor package, according to an embodiment.

A controller 1110 and a memory 1120 may be arranged in the memory card 1100 to exchange electrical signals with each other. For example, when the controller 1110 issues a command to the memory 1120, the memory 1120 may transmit data to the controller 1110. The controller 1110 and/or the memory 1120 may include a semiconductor package according to one of the embodiments of the inventive concept. The memory 1120 may include a memory array (not shown) or a memory array bank (not shown).

The memory card 1100 may be used in card-type memory devices, such as a memory stick card, a smart media (SM) card, a secure digital (SD) card, a mini-SD card, and a multimedia card (MMC).

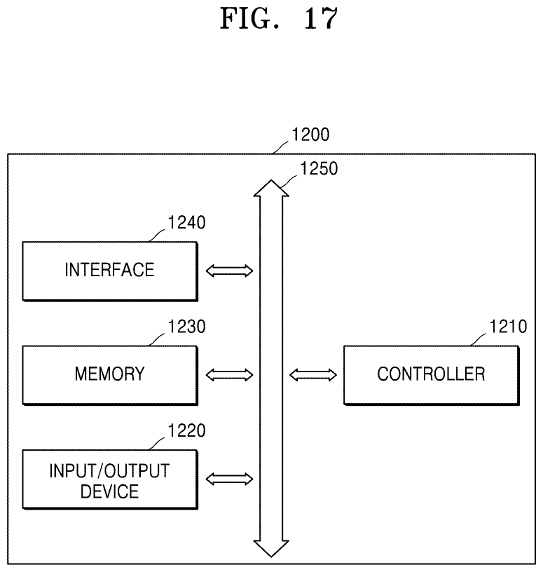

FIG. 17 is a schematic block diagram of an electronic system 1200 including a semiconductor package, according to an embodiment.

The electronic system 1200 may include a controller 1210, an input/output device 1220, a memory 1230, and an interface 1240. The electronic system 1200 may correspond to a mobile system or a system that transmits or receives information. The mobile system may include a personal digital assistant (PDA), a portable computer, a web tablet, a wireless phone, a mobile phone, a digital music player, or a memory card.

The controller 1210 may execute a program and control the electronic system 1200. For example, the controller 1210 may include a microprocessor, a digital signal processor, a microcontroller, or the like. The input/output device 1220 may be used to input data to or output data from the electronic system 1200.

The electronic system 1200 may be connected to and may exchange data with an external device, e.g., a personal computer (PC) or a network, through the input/output device 1220. For example, the input/output device 1220 may include a keypad, a keyboard, or a display. The memory 1230 may store code and/or data for the operation of the controller 1210 and/or data processed by the controller 1210.

The controller 1210 and the memory 1230 may include a semiconductor package according to one of the embodiments of the inventive concept. The interface 1240 may correspond to a data transmission passage between the electronic system 1200 and an external device. The controller 1210, the input/output device 1220, the memory 1230, and the interface 1240 may communicate with one another through a bus 1250.

For example, the electronic system 1200 may be used in a mobile phone, an MP3 player, a navigation device, a portable multimedia player (PMP), a solid-state disk (SSD), or household appliances.

While the inventive concept has been particularly shown and described with reference to embodiments thereof, it will be understood that various changes in form and details may be made therein without departing from the scope of the following claims.

What is claimed is:

1. A semiconductor package comprising:
a first semiconductor chip; and
a second semiconductor chip hybrid-bonded to the first semiconductor chip,
wherein the first semiconductor chip comprises a plurality of first main pads and a first bonding insulation layer extending around the plurality of first main pads, wherein the plurality of first main pads are spaced apart from each other, and wherein each of the plurality of first main pads comprises a plurality of first sub main pads spaced apart from each other,
wherein the second semiconductor chip comprises a plurality of second main pads and a second bonding insulation layer extending around the plurality of second main pads, wherein the plurality of second main pads are spaced apart from each other, and
wherein the plurality of second main pads are aligned with the plurality of first main pads, wherein each of the plurality of second main pads comprises a plurality of second sub main pads spaced apart from each other, wherein each of the plurality of second sub main pads is bonded to a respective one of the plurality of first sub main pads, and wherein the second bonding insulation layer is bonded to the first bonding insulation layer.

2. The semiconductor package of claim 1, wherein a top surface of each of the plurality of first main pads is coplanar with a top surface of the first bonding insulation layer, and wherein a bottom surface of each of the plurality of second main pads is coplanar with a bottom surface of the second bonding insulation layer.

3. The semiconductor package of claim 1, wherein the first bonding insulation layer is between the plurality of first sub main pads, and the second bonding insulation layer is between the plurality of second sub main pads.

4. The semiconductor package of claim 1, wherein each of the plurality of first main pads is divided by the first bonding insulation layer into the plurality of first sub main pads, and each of the plurality of second main pads is divided by the second bonding insulation layer into the plurality of second sub main pads.

5. The semiconductor package of claim 1, wherein each of the first bonding insulation layer and the second bonding insulation layer comprises a silicon oxide layer or a silicon nitride layer.

6. The semiconductor package of claim 1, wherein a thickness of each of the plurality of second sub main pads is less than a thickness of each of the plurality of first sub main pads.

7. The semiconductor package of claim 1, wherein a width of each of the plurality of second sub main pads is equal to a width of each of the plurality of first sub main pads.

8. The semiconductor package of claim 1, wherein each of the plurality of second sub main pads is bonded to a respective one of the plurality of first sub main pads at a respective bonding region, and wherein the second bonding insulation layer is bonded to the first bonding insulation layer at an insulating bonding region.

9. The semiconductor package of claim 1, wherein the plurality of first main pads are in a first main pad region located in a central region of the first semiconductor chip in a plan view, and the plurality of second main pads are in a second main pad region located in a central region of the second semiconductor chip in the plan view.

10. The semiconductor package of claim 9, wherein the first semiconductor chip further comprises a first dummy pad region in a peripheral region that extends around the first main pad region, wherein the first dummy pad region comprises first dummy pads arranged therein, and
wherein the second semiconductor chip further comprises a second dummy pad region in a peripheral region that extends around the second main pad region, wherein the second dummy pad region comprises second dummy pads arranged therein.

11. A semiconductor package comprising:
a first semiconductor chip; and
a second semiconductor chip hybrid-bonded to the first semiconductor chip,
wherein the first semiconductor chip comprises a plurality of first main pads, a first bonding insulation layer extending around the plurality of first main pads, and a support pad, wherein the plurality of first main pads are spaced apart from each other, wherein each of the plurality of first main pads comprises a plurality of first sub main pads spaced apart from each other, and wherein the plurality of first sub main pads are on the support pad,
wherein the second semiconductor chip comprises a plurality of second main pads and a second bonding insulation layer extending around the plurality of second main pads, wherein the plurality of second main pads are spaced apart from each other,
wherein each of the plurality of second main pads comprises a plurality of second sub main pads spaced apart from each other, wherein the second semiconductor chip further comprises a support via, and wherein the plurality of second sub main pads are on the support via, wherein each of the plurality of second sub main pads is bonded to a respective one of the plurality of first sub main pads, and wherein the second bonding insulation layer is bonded to the first bonding insulation layer.

12. The semiconductor package of claim 11, wherein the first bonding insulation layer is between the plurality of first sub main pads, and wherein the support pad is spaced apart from the first bonding insulation layer.

13. The semiconductor package of claim 11, wherein the second bonding insulation layer is between the plurality of second sub main pads, and wherein the support via is on the second bonding insulation layer and the plurality of second sub main pads.

14. The semiconductor package of claim 11, wherein a width of the support pad is greater than a width of each of the plurality of first main pads.

15. The semiconductor package of claim 11, wherein a width of the support via is greater than a width of each of the plurality of second sub main pads.

16. A semiconductor package comprising:
a first semiconductor chip; and
a second semiconductor chip hybrid-bonded to the first semiconductor chip,
wherein the first semiconductor chip comprises a first substrate structure, a plurality of first main pads on the first substrate structure, and a first bonding insulation structure extending around the plurality of first main pads, wherein the first substrate structure comprises a support pad, and wherein the plurality of first main pads are spaced apart from each other, wherein each of the plurality of first main pads comprises a plurality of first sub main pads spaced apart from each other, and wherein the plurality of first sub main pads are supported by the support pad,
wherein the second semiconductor chip comprises a second substrate structure, a plurality of second main pads spaced apart from each other, and a second bonding insulation structure extending around the plurality of second main pads, and wherein the second substrate structure comprises a support via,
wherein each of the plurality of second main pads includes a plurality of second sub main pads spaced apart from each other, wherein the plurality of second sub main pads are supported by the support via, wherein each of the plurality of second sub main pads is bonded to a respective one of the plurality of first sub main pads, and wherein the second bonding insulation structure is bonded to the first bonding insulation structure.

17. The semiconductor package of claim 16, wherein the first substrate structure further comprises a wiring layer, and wherein the support pad is in the wiring layer and supports each of the plurality of first main pads.

18. The semiconductor package of claim 16, wherein the second substrate structure further comprises a silicon layer, and wherein the support via supports each of the plurality of second main pads.

19. The semiconductor package of claim 16, wherein the first bonding insulation structure comprises a plurality of insulating layers, and wherein the second bonding insulation structure comprises a plurality of insulating layers.

20. The semiconductor package of claim 16, wherein a width of the support pad is greater than a width of each of the plurality of first main pads, and wherein a width of the support via is greater than a width of each of the plurality of second sub main pads.
